(19) United States
(12) Patent Application Publication
(10) Pub. No.: US 2008/0122074 A1
(43) Pub. Date: May 29, 2008

(54) Multi-chip electronic circuit module and a method of manufacturing

(75) Inventors: Raymond Wong, Alhambra, CA (US); Steven W. Schell, Torrance, CA (US); Mau-Chung Frank Chang, Los Angeles, CA (US)

Correspondence Address: DLA PIPER US LLP, 2000 UNIVERSITY AVENUE, E. PALO ALTO, CA, 94303-2248, US

(73) Assignee: Silicon Storage Tech., Inc.

(21) Appl. No.: 11/605,890

(22) Filed: Nov. 28, 2006

(51) Int. Cl. H01L 23/34; H01L 21/00

(52) U.S. Cl. 257/724; 438/106; 257/E23.08; 257/E21.001

(57) ABSTRACT

An integrated circuit module has a substrate with an exposed surface. An integrated circuit die has a first surface and a second surface opposite the first surface, and has a plurality of bonding pads on the second surface. The integrated circuit die is positioned with its first surface on the exposed surface of the substrate. A plurality of dielectric layers cover the second surface of the integrated circuit die. At least one conductive layer is sandwiched between a pair of the plurality of dielectric layers, and forms one or more passive elements electrically connected to the plurality of bonding pads of the integrated circuit die, through one or more holes in one of the plurality of dielectric layers.

### TECHNICAL FIELD

The present invention relates to a multi-chip electronic circuit package module in which passive components, such as resistor, capacitor, inductor or distributed microwave structure and circuits are also formed, and in a method of forming such a module using Panel-Scale-Packaging (PSP) technology.

### BACKGROUND OF THE INVENTION

Integrated circuit dies comprising of electronic circuits formed in a single semiconductor die also well known in the art. Typically, these integrated circuit dies are formed of active components, i.e. transistors, in a single crystalline substrate, and may be analog circuits or digital circuits or a mixture of the two. It has been known in the prior art to use the capacitance of a transistor as a capacitor.

Passive components, such as resistors, capacitors, and inductors are also well known in the art. Although these passive components have been integrated with active components, such as integrated circuit dies in the same die, the problem has been the limited quality factor from the high metal losses and limited area for cost effectiveness.

Multi-chip Package (MCP) modules are also well known in the art. In a MCP module, many integrated circuit dies are electrically connected and then packaged together in a single module. The advantage of a MCP module is that different integrated circuits can be fabricated to optimize performance and possibly cost savings, and then packaged together without the necessity of forming them all together in a single die.

MCP using a glass, or metal or ceramic substrate is also well known. See for example, U.S. patent application 2003/0122246 published Jul. 3, 2003; and U.S. patent application 2003/0122243 published Jul. 3, 2003. However, heretofore, the formation of a MCP module with a wide range of passive components, such as distributed microwave structures and circuits, spiral inductors, multi-layer inductors, MIM capacitors, stacked MIM capacitors, multi-layer transformers and baluns, filters, baluns, phase shifters, diplexers, and matching circuits, which are packaged within the MCP itself, and specifically sandwiched between a pair of dielectric layers, has not been done.

### SUMMARY OF THE INVENTION

In the present invention, an electronic circuit module comprises a substrate having an exposed surface. An integrated circuit die, having a first surface and a second surface opposite the first surface and has a plurality of bonding pads on the second surface and is positioned with its first surface on the exposed surface of the substrate. A plurality of dielectric layers cover the second surface of the integrated circuit die. At least one conductive layer is sandwiched between a pair of the plurality of dielectric layers, forming one or more passive elements, and is electrically connected to the plurality of bonding pads of the integrated circuit die, formed through one or more holes in one of the plurality of dielectric layers.

### BRIEF DESCRIPTION OF THE DRAWINGS

FIG. 1 is an electrical circuit top view of a multi-chip module (MCP) of the present invention.

FIGS. 2(a-b) are top views of the steps of making the MCP of the present invention shown on a substrate. FIGS. 2(c-i) are enlarged top views of the subsequent steps of making the MCP of the present invention showing the MCP portion on the substrate.

FIGS. 2(a-i)-1 are side views of the corresponding steps shown in FIGS. 2(a-i) for making the MCP of the present invention.

### DETAILED DESCRIPTION OF THE INVENTION

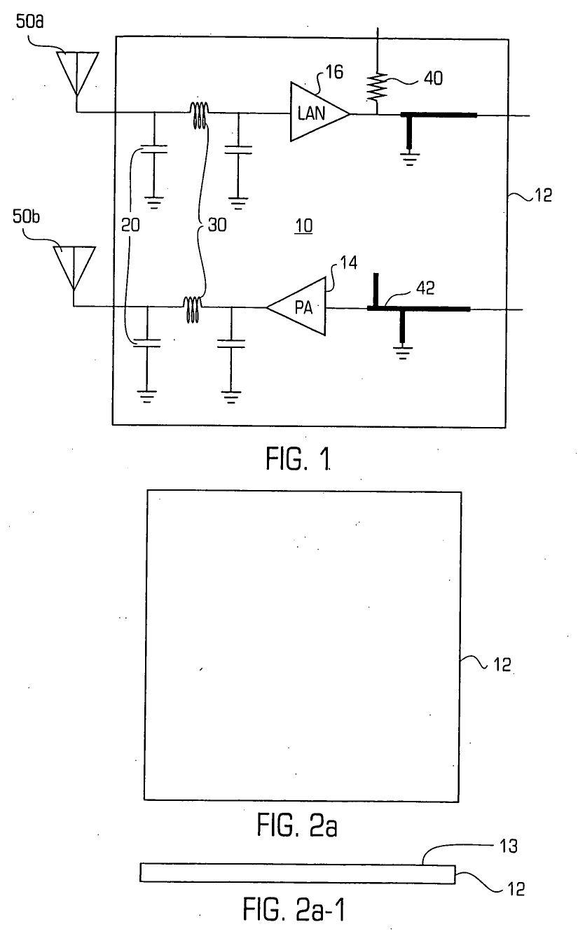

Referring to FIG. 1 there is shown a multi-chip module (MCP) 10 of the present invention. The MCP 10 comprises a substrate 12, such as ceramics, glass or metal, upon which has been placed two integrated circuit dies 14 and 16. The integrated circuit dies 14 and 16 in the preferred embodiment are analog circuits, such as a power amplifier (PA) 14 and a low noise amplifier (LNA) 16. However, it should be noted that the MCP 10 and the method of the present invention can be practiced with digital circuit dies as well. The MCP 10 further comprises passive components such as capacitors 20, inductors 30, and resistors 40. Other passive components, (which are not shown) but which may be formed by the present invention include, but are not limited to distributed microwave structures and circuits, spiral inductors, multi-layer inductors, MIM capacitors, stacked MIM capacitors, multi-layer transformers and baluns, filters, baluns, phase shifters, diplexers, and matching circuits. Thus, as used herein and in the claims, the term “passive component” means a component which is not an “active component”, with an “active component” meaning an electronic component that requires a source of energy to perform its intended function. Thus, a diode or a transistor or a thyristor is an active component. Thus, one use of the MCP 10 is as a power amplifier transceiver. Electro-magnetic radiation signals, such as RF signals, are received by an antenna 50a and are supplied to the capacitors 20 and inductor 30 which serves as a filter, and are then supplied to the input of the LNA 16. The output of the LNA 16 is supplied to a transmission line having a trimmed resistor 40 as a part thereof, and is supplied by the MCP 10 to other electronic components (not shown). The MCP 10 also receives signals from other components, via a transmission line 42 and is supplied to the input of the PA 14. The output of the PA 14 is supplied to a filter comprising a capacitor 20 and inductor 30, and then to the antenna 50b for transmission.

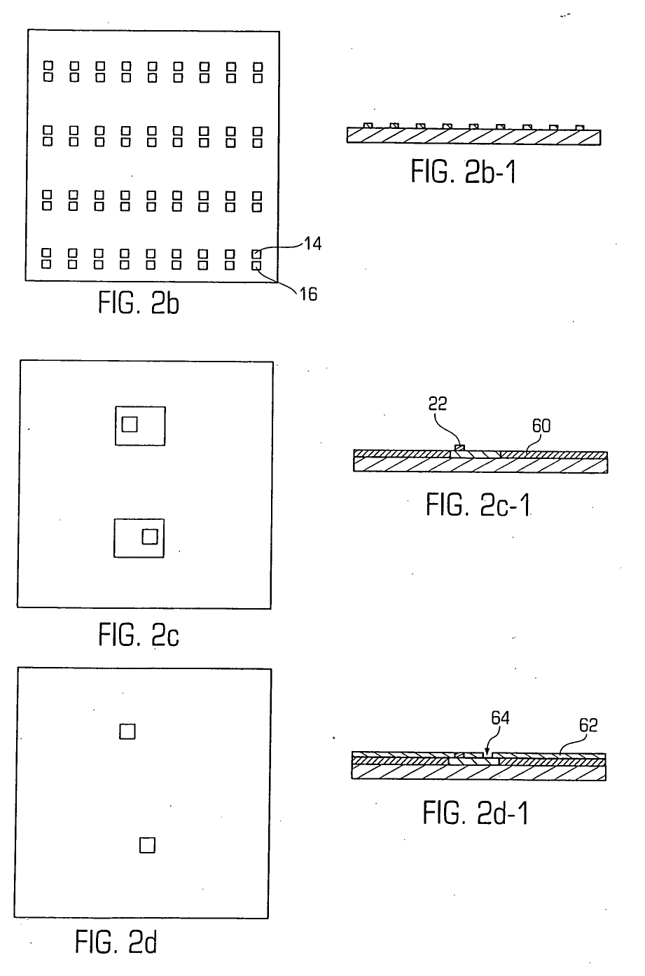

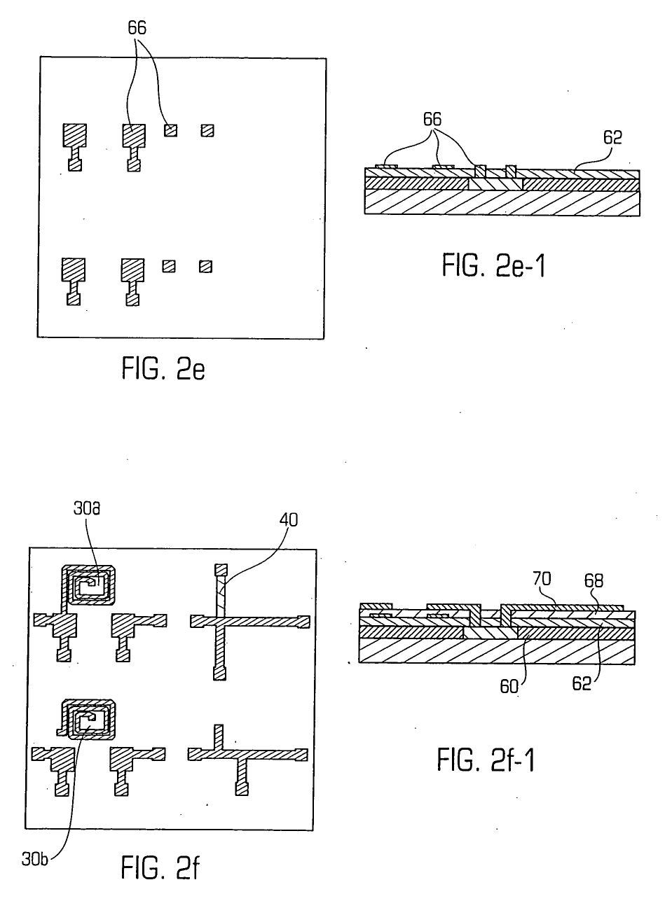

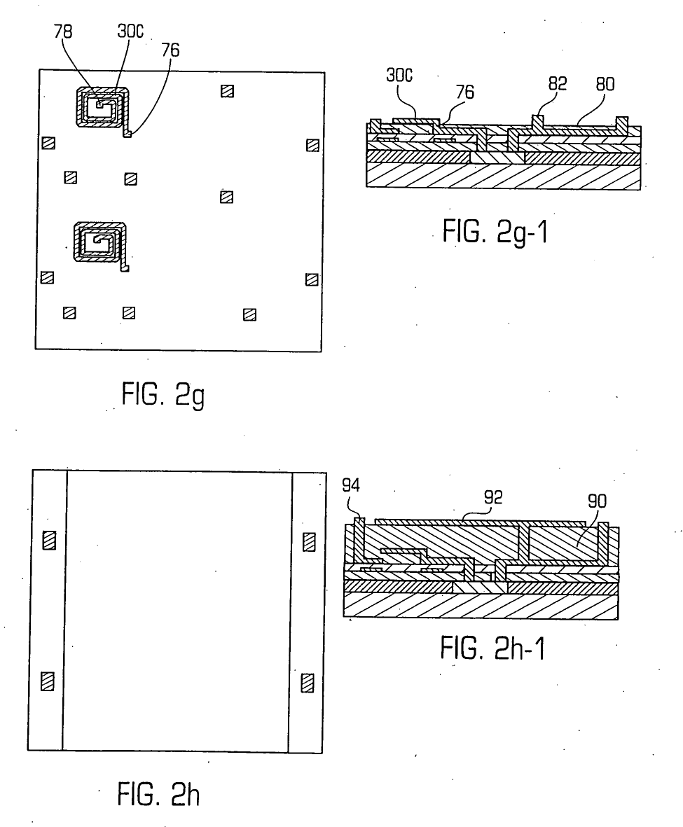

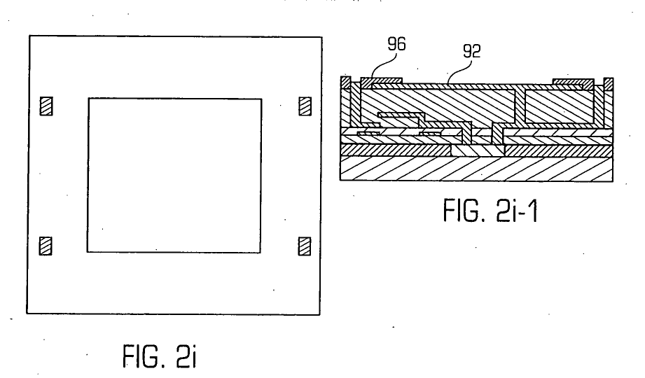

Referring to FIG. 2a there is shown the first step in the method of the present invention. In the first step of the method of the present invention, a substrate 12 is provided. The substrate 12 can be made of any rigid type of material, such as glass, ceramic or even metal, in a panel form. The substrate 12 has an exposed top surface 13. Preferably, the substrate 12 is made of a panel material which is used in PSP technology.

Referring to FIG. 2b, there is shown the next step in the method of the present invention. In the next step, an adhesive is first applied to the substrate panel 12, and then integrated circuit dies 14 and 16 are placed on the substrate panel 12 to be securely attached thereto. Each of the integrated circuit dies 14 and 16 are placed upon the exposed surface 13 of the substrate panel 12 via a pick and place process, which is well known. The integrated circuit dies 14 and 16 are placed in a plurality of groups (shown within a circle) with each group comprising one die 14 and one die 16. Of course, each group may contain only one die or may contain more than the two dies 14 and 16. As is well known in the art, when the dies 14 and 16 are fabbed, each of the dies 14 and 16 has a first surface and a second surface opposite thereto, with the second surface containing bonding pads 22. The first surface is placed downward facing the exposed surface 13 of the panel 12. Thus, the bonding pads 22 are exposed.

Referring to FIG. 2c, there is shown the next step in the method of the present invention, in the fabrication of the MCP 10 of the present invention, wherein just the MCP 10 portion of the substrate 12 is shown. In the next step shown in FIG. 2c, a dielectric material 60, such as silicon rubber is placed on the exposed surface 13 of the substrate 12 adjacent to the integrated circuit dies 14 and 16. Thus, the surface 13 of the substrate 12 is covered by either the silicon rubber 60 or is covered by the dies 14 and 16. The silicon rubber 60 serves as a filler so that it can be planarized.

Referring to FIG. 2d, there is shown the next step in the method of the present invention. A first dielectric material 62 covers the silicon rubber 60 and the dies 14 and 16. Where the bonding pads 22 are formed on the second surface of the die 14 and 16, vias 64 or holes 64 are formed through the first dielectric material 62 to expose the bonding pads 22.

Referring to FIG. 2e, there is shown the next step in the method of the present invention. A first metallization layer 66 is placed on the first dielectric layer 62, and is patterned. The first metallization layer 66 is patterned to create passive elements such as the bottom plate of a capacitor 20. The patterning can be accomplished by conventional lithography/etch process. The first metallization layer 66 also fills the vias 64 and contacts the bonding pads 22 on the second surface of the dies 14 and 16 to form an interconnect.

Referring to FIG. 2f, there is shown the next step in the method of the present invention. A second dielectric layer 68 is deposited or formed on the first metallization layer 66 and on the first dielectric layer 62. The thickness of the second dielectric layer 68 depends on the desired capacitance of the capacitor 20 to be formed. The second dielectric layer 68 is then planarized, again by conventional processes, such as reflow or CMP. Similar to the process used for the first dielectric layer 62, vias or holes 64 are then formed in the second dielectric 68 to contact the first metallization layer 66 in the contact holes 64 to connect to the bonding pads 22 of the dies 14 and 16. Thereafter, a second metallization layer 70 is formed on the second dielectric layer 68. The second metallization layer 70 fills the contact holes 64 and connects to the first metallization layer 66 in the contact holes 64 and connects to the bonding pads 22 of the dies 14 and 16. The second metallization layer 70 is then patterned forming portions of the passive component, such as the top plate of a capacitor 20. In addition, the second metallization layer 70 can be patterned to form resistors 40 and inductors 30 which are connected to the bonding pads 22 of the dies 14 and 16 or to the top plate of the capacitors 20 formed on the second dielectric layer 68. In the event the second metallization layer 70 is used to form resistors, an additional thin-film material is required, as is well known in the art. The position of the layer at which the resistors 40, inductors 30 and capacitors 20 are formed is arbitrary. They will depend on the layer structure chosen and if desired, there may be several layers that support the capacitors 20 and the resistors 40. The patterning of the second metallization layer 70 can again be done by conventional lithography using conventional etching process.

Referring to FIG. 2g, there is shown the next step in the method of the present invention. A third dielectric layer 80 can be deposited or formed on the second metallization layer 70, and on the second dielectric layer 68. The third dielectric layer 80 can then be planarized, similar to the second dielectric layer. A third metallization layer 82 can be formed on the third dielectric layer 80. The third metallization layer 82 can be patterned to form passive elements such as additional inductors 30c. In addition, vias or interconnect holes 76 and 78 can be formed in the third dielectric layer 80 to connect the inductor 30c to the second metallization layer 70.

A fourth dielectric layer such as BPSG 90 can be deposited on the structure shown in FIG. 2g. A grounding plane 92 is formed on the BPSG layer 90 and interconnects 94 can be made through vias or holes in the BPSG layer 90 to connect to the underlying layer(s) beneath the BPSG layer 90. The resultant structure is shown in FIG. 2h.

Finally, a passivation layer 96 can be formed ion the structure shown in FIG. 2h to protect the structure, while allowing access to the grounding plane 92 and the interconnects 94. The resultant structure is shown in FIG. 2i

There are many advantages to the device and method of the present invention. First, by using PSP technology, a complex RF systems with all passive components are formed within the package itself. This allows the creation of a low cost, ultra-thin, compact, and high performance RF system.

Second, by using PSP technology wherein MCP modules are fabricated from a large scale panel based assembly, this provides lowest cost highest volume integration technique for mass production. Presently up to 50″ panels are being used in the flat-panel display industry; thus, the same potential exists for use in the method of the present invention.

Third, because routing and passive components are formed between thin dielectrics, the thickness of the final MCP package is only limited by the thickness of the dies in the package and the panel material that the dies are adhered to. Total package thicknesses can be as thin as 0.4 mm.

Fourth, because the device is a MCP device forming an RF system, many dies using different technologies, such as SiGe, CMOS, GaAs, etc. can be used. The ability to integrate any of these chip technologies into the package allows for the design of a complex system with sub-block performances optimized with a specific technology.

Fifth, using fabrication technology from semiconductor fabrication, fine line geometries on the order of 10 um allow for high density interconnects and the ability to produce highly repeatable parasitics for unit-to-unit conformity. The use of via holes and interconnects create short, precise, and consistent connections to the chip bond pads as opposed to normal bond-wiring or flip-chip configurations.

Lastly, depending on the complexity of the system any number of metal layers and dielectric layers can be used with each of different thicknesses and permittivity. The ability to construct multi-layers in conjunction with the thick metal traces (˜6 um) allow for the integration of high quality factor passive components, which are described heretofore.

What is claimed is:

1. An integrated circuit module comprising:
a substrate having an exposed surface;
an integrated circuit die, having a first surface and a second surface opposite said first surface and having a plurality of bonding pads on said second surface;
said integrated circuit die, positioned with its first surface on said exposed surface of said substrate;
a plurality of dielectric layers covering said second surface of said integrated circuit die; and
at least one conductive layer sandwiched between a pair of said plurality of dielectric layers, forming one or more passive elements electrically connected to said plurality of bonding pads of said integrated circuit die, formed through one or more holes in one of said plurality of dielectric layers.

2. The integrated circuit module of claim 1 wherein said integrated circuit die is an analog circuit.

3. The integrated circuit module of claim 2 wherein said integrated circuit die is an RF analog circuit.

4. The integrated circuit module of claim 1 wherein said integrated circuit die is a digital circuit.

5. The integrated circuit module of claim 1 wherein said integrated circuit die has a first thickness.

6. The integrated circuit module of claim 5 further comprising:
a first layer covering portions of said portions of said exposed surface of said substrate not contacted by said integrated circuit die, with said first layer having a thickness substantially the same as the first thickness; and
wherein said plurality of dielectric layers cover said second surface of said integrated circuit die and said first layer.

7. The integrated circuit module of claim 1 wherein said passive element is an element selected from a resistor, an inductor and a capacitor.

8. The integrated circuit module of claim 6 wherein said first layer is a silicon based rubber.

9. The integrated circuit module of claim 8 wherein said substrate is a material made from metal, glass or ceramic.

10. A multi-chip analog module comprising:
a substrate having an exposed surface;
a plurality of analog integrated circuit dies, each having a first surface and a second surface opposite said first surface and having a plurality of bonding pads on said second surface;
each of said integrated circuit dies positioned with its first surface on said exposed surface of said substrate;
a dielectric layer covering said second surface of said plurality of integrated circuit dies; and
one or more passive elements formed on said dielectric layer electrically connected to said bonding pads of said plurality of integrated circuit dies through one or more holes formed in said dielectric layer.

11. The module of claim 10 wherein each of said analog integrated circuit die is an RF analog circuit die.

12. The module of claim 10 wherein said one or more passive elements is a resistor, a capacitor or an inductor.

13. The module of claim 12 wherein said plurality of integrated circuits are a first amplifier and a second amplifier, said first amplifier having a first input for receiving an electro-magnetic radiation signal and wherein said passive element comprises a first filter connected to said first input;
said second amplifier having a first output for producing an electro-magnetic radiation and wherein said passive element comprises a second filter connected to said first output.

14. The module of claim 13 wherein said first amplifier has a second output and wherein said passive element further comprises a first transmission line connected thereto.

15. The module of claim 14 wherein said second amplifier has a second input and wherein said passive element further comprises a first transmission line connected thereto.

16. A method of manufacturing a multi-chip module, said method comprising:
placing a plurality of integrated circuit dies on a substrate; said substrate having an exposed surface, each of said integrated circuit dies has a first surface and a second surface opposite said first surface, said second surface having a plurality of bonding pads, each of said plurality of integrated circuit dies placed in a plurality of groups, with each group having a plurality of dies, with the first surface of each die on said exposed surface;
covering said plurality of integrated circuit dies by a first layer of dielectric material, said first layer of dielectric material covering the second surface of said integrated circuit dies;
forming one or more passive elements for each group of integrated circuit dies on said first layer of dielectric material;
connecting each of said one or more passive elements associated with each group of integrated circuit dies to the associated bonding pads, through at least one hole formed in said first layer of dielectric material; and
covering said passive elements with a second layer of dielectric material.

17. The method of claim 16 further comprising:
cutting each group of integrated circuit dies and their associated passive elements.

18. The method of claim 16 wherein the step of covering said plurality of integrated circuit dies by a first layer of dielectric material also covers the exposed surface of said substrate upon which the integrated circuit dies are not placed.

19. The method of claim 16 further comprising the step of forming a plurality of holes through said first layer of dielectric material, with at least one hole associated with each group of integrated circuit dies, and wherein each of said one or more passive elements associated with each group of integrated circuit dies is connected to the associated bonding pads, through at least one hole formed in said first layer of dielectric material, associated with each group of integrated circuit dies.
